(19) United States
(12) Patent Application Publication
(10) Pub. No.: US 2017/0130324 A1
(43) Pub. Date: May 11, 2017

(54) VACUUM EVAPORATION METHOD

(71) Applicants: Tsinghua University, Beijing (CN); HON HAI PRECISION INDUSTRY CO., LTD., New Taipei (TW)

(72) Inventors: YANG WEI, Beijing (CN); SHOU-SHAN FAN, Beijing (CN)

(21) Appl. No.: 15/252,692

(22) Filed: Aug. 31, 2016

(30) Foreign Application Priority Data
Nov. 11, 2015 (CN) 201510764078.5

(51) Int. Cl. C23C 14/24; C23C 14/58

(52) U.S. Cl. CPC C23C 14/24; C23C 14/58

(57) ABSTRACT

A vacuum evaporation method includes steps of: providing an evaporating source and a depositing substrate; spacing the depositing substrate and the evaporating source from each other in a vacuum room and vacuumizing the vacuum room; and inputting electrical signals to the carbon nanotube film structure from the first electrode and the second electrode to gasify the evaporating material to form a deposited layer on the depositing substrate.

### CROSS-REFERENCE TO RELATED APPLICATIONS

This application claims priority to Chinese Patent Application No. 201510764078.5, filed on Nov. 11, 2015, the disclosure of which is incorporated herein by reference.

### FIELD

The present disclosure relates to a vacuum evaporation method.

### BACKGROUND

A vacuum evaporation is a process of heating an evaporating source in vacuum to gasify and deposit the evaporating source material on a surface of a substrate to form a film. In order to form a uniform thin film, it is necessary to form a uniform gaseous evaporating material around the substrate. Conventionally, a complex gas guiding device is used to uniformly transfer the gaseous evaporating material to the surface of the depositing substrate.

### BRIEF DESCRIPTION OF THE DRAWINGS

Implementations of the present technology will now be described, by way of example only, with reference to the attached figures.

FIG. 1 is a side view of one embodiment of a vacuum evaporation apparatus.

FIG. 2 is a vertical view of one embodiment of an evaporating source.

FIG. 3 is a scanning electron microscope (SEM) image of a carbon nanotube film drawn from a carbon nanotube array.

FIG. 4 is an SEM image of a carbon nanotube film structure.

FIG. 5 is a side view of another embodiment of the evaporating source.

FIG. 6 is a vertical view of another embodiment of the evaporating source.

FIG. 7 and FIG. 8 are SEM images of one embodiment of the evaporating source under different resolutions.

FIG. 9 is an SEM of another embodiment of the evaporating source after evaporation.

FIG. 10 is an SEM image of one embodiment of a deposited layer.

FIG. 11 is an X-ray diffraction (XRD) image of one embodiment of the deposited layer.

FIG. 12 is a side view of another embodiment of the evaporating source.

FIG. 13 is flowchart of one embodiment of a vacuum evaporation method.

FIG. 14 is a side view of another embodiment of the evaporating source.

FIG. 15 is a side view of another embodiment of the evaporating source.

FIG. 16 is flowchart of another embodiment of a vacuum evaporation method.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one”.

It will be appreciated that for simplicity and clarity of illustration, where appropriate, reference numerals have been repeated among the different figures to indicate corresponding or analogous elements. In addition, numerous specific details are set forth in order to provide a thorough understanding of the embodiments described herein. However, it will be understood by those of ordinary skill in the art that the embodiments described herein can be practiced without these specific details. In other instances, methods, procedures, and components have not been described in detail so as not to obscure the related relevant feature being described. Also, the description is not to be considered as limiting the scope of the embodiments described herein. The drawings are not necessarily to scale and the proportions of certain parts may be exaggerated to better illustrate details and features of the present disclosure.

Several definitions that apply throughout this disclosure will now be presented.

The term “comprise” or “comprising” when utilized, means “include or including, but not necessarily limited to”; it specifically indicates open-ended inclusion or membership in the so-described combination, group, series, and the like.

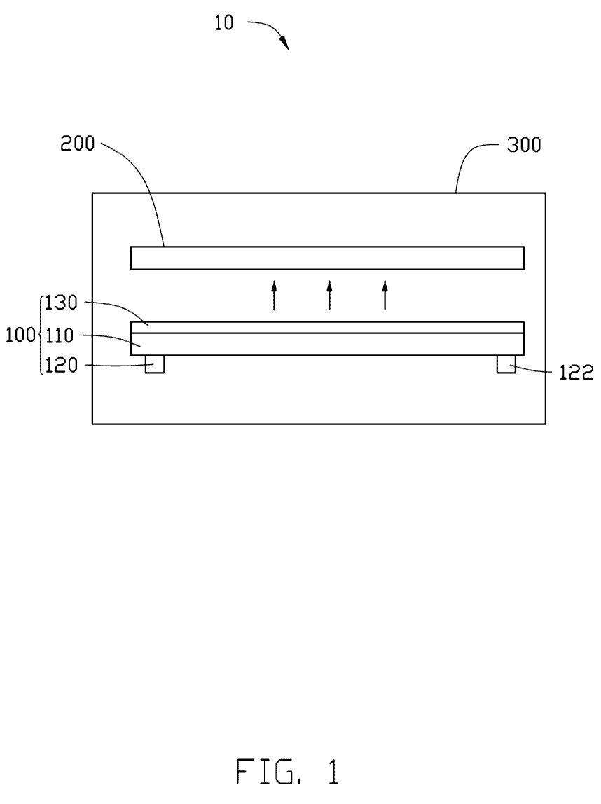

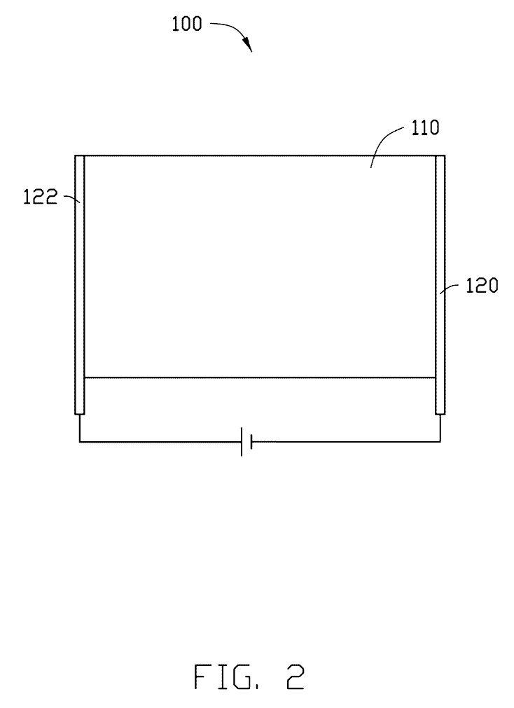

Referring to FIG. 1 and FIG. 2, one embodiment provides a vacuum evaporation apparatus 10. The vacuum evaporation apparatus 10 comprises an evaporating source 100, a depositing substrate 200, and a vacuum room 300. The evaporating source 100 and the depositing substrate 200 are located in the vacuum room 300. The depositing substrate 200 and the evaporating source 100 are faced to and spaced from each other. In one embodiment, a distance between the depositing substrate 200 and the evaporating source 100 is in a range from about 1 micrometer to about 10 millimeters.

The evaporating source 100 comprises a carbon nanotube film structure 110, a first electrode 120, a second electrode 122, and an evaporating material 130. The first electrode 120 and the second electrode 122 are spaced from each other and electrically connected to the carbon nanotube film structure 110. The carbon nanotube film structure 110 is a carrying structure for the evaporating material 130. The evaporating material 130 is located on a surface of the carbon nanotube film structure 110. In one embodiment, the carbon nanotube film structure 110 is suspended by the first electrode 120 and the second electrode 122. The evaporating material 130 is located on a surface of the suspended carbon nanotube film structure 110. The carbon nanotube film structure 110 which is coated by the evaporating material 130 is facing to and spaced from a depositing surface of the depositing substrate 200. A distance between the depositing substrate 200 and the carbon nanotube film structure 110 is in a range from about 1 micrometer to about 10 millimeters.

The carbon nanotube film structure 110 is a resistive element. The carbon nanotube film structure 110 has a small heat capacity per unit area, and has a large specific surface area but a minimal thickness. In one embodiment, the heat capacity per unit area of the carbon nanotube film structure 110 is less than 2×10⁻⁴ J/cm²·K. In another embodiment, the heat capacity per unit area of the carbon nanotube film structure 110 is less than 1.7×10⁻⁶ J/cm²·K. The specific surface area of the carbon nanotube film structure 110 is larger than 200 m²/g. The thickness of the carbon nanotube film structure 110 is less than 100 micrometers. The first electrode 120 and the second electrode 122 input electrical signals to the carbon nanotube film structure 110. Since the carbon nanotube film structure 110 has a small heat capacity per unit area, the carbon nanotube film structure 110 can convert electrical energy to heat quickly, and a temperature of the carbon nanotube film structure 110 can rise rapidly. Since the carbon nanotube film structure 110 has a large specific surface area and is very thin, the carbon nanotube film structure 110 can rapidly transfer heat to the evaporating material 130. The evaporating material 130 is rapidly heated to a evaporation or sublimation temperature.

The carbon nanotube film structure 110 comprises a single carbon nanotube film, or at least two stacked carbon nanotube films. The carbon nanotube film comprises a plurality of nanotubes. The plurality of nanotubes are generally parallel to each other, and arranged substantially parallel to a surface of the carbon nanotube film structure 110. The carbon nanotube film structure 110 has uniform thickness. The carbon nanotube film can be regarded as a macro membrane structure. In the macro membrane structure, an end of one carbon nanotube is joined to another end of an adjacent carbon nanotube arranged substantially along the same direction by Van der Waals attractive force. The carbon nanotube film structure 110 and the carbon nanotube film have a macro area and a microscopic area. The macro area denotes a membrane area of the carbon nanotube film structure 110 or the carbon nanotube film when the carbon nanotube film structure 110 or the carbon nanotube film is regarded as a membrane structure. In terms of a microscopic area, the carbon nanotube film structure 110 or the carbon nanotube film is a network structure having a large number of nanotubes joined end to end. The microscopic area signifies a surface area of the carbon nanotubes actually carrying the evaporating material 130.

In one embodiment, the carbon nanotube film is formed by drawing from a carbon nanotube array. This carbon nanotube array is grown on a growth surface of a substrate by chemical vapor deposition method. The carbon nanotubes in the carbon nanotube array are substantially parallel to each other and perpendicular to the growth surface of the substrate. Adjacent carbon nanotubes make mutual contact and combine by van der Waals forces. By controlling the growth conditions, the carbon nanotube array is substantially free of impurities such as amorphous carbon or residual catalyst metal particles. The carbon nanotube array being substantially free of impurities with carbon nanotubes in close contact with each other, there is a larger van der Waals forces between adjacent carbon nanotubes. When carbon nanotube fragments (CNT fragments) are drawn, adjacent carbon nanotubes are continuously drawn out end to end by van der Waals forces to form a free-standing and uninterrupted macroscopic carbon nanotube film. The carbon nanotube array made of carbon nanotubes drawn end to end is also known as a super-aligned carbon nanotube array. In order to grow the super-aligned carbon nanotube array, the growth substrate material can be a P-type silicon, an N-type silicon, or a silicon oxide substrate.

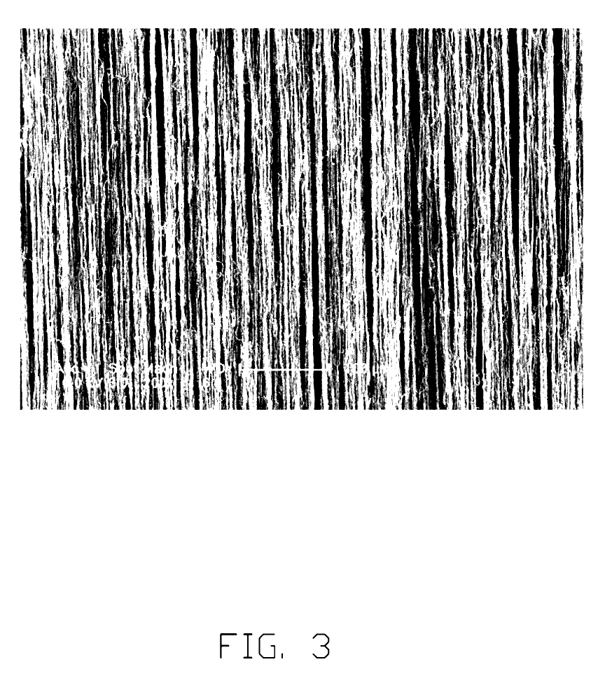

The carbon nanotube film includes a plurality of carbon nanotubes that can be joined end to end and arranged substantially along the same direction. Referring to FIG. 3, a majority of carbon nanotubes in the carbon nanotube film can be oriented along a preferred orientation, meaning that a large number of the carbon nanotubes in the carbon nanotube film are arranged substantially along the same direction. An end of one carbon nanotube is joined to another end of an adjacent carbon nanotube arranged substantially along the same direction by Van der Waals attractive force. A small number of the carbon nanotubes are randomly arranged in the carbon nanotube film, and has a small if not negligible effect on the larger number of the carbon nanotubes in the carbon nanotube film arranged substantially along the same direction.

More specifically, the carbon nanotube drawn film includes a plurality of successively oriented carbon nanotube segments joined end-to-end by Van der Waals attractive force therebetween. Each carbon nanotube segment includes a plurality of carbon nanotubes substantially parallel to each other, and joined by Van der Waals attractive force therebetween. The carbon nanotube segments can vary in width, thickness, uniformity and shape. The carbon nanotubes in the carbon nanotube drawn film are also substantially oriented along a preferred orientation.

Microscopically, the carbon nanotubes oriented substantially along the same direction may not be perfectly aligned in a straight line, and some curve portions may exist. It can be understood that some carbon nanotubes located substantially side by side and oriented along the same direction in contact with each other cannot be excluded. The carbon nanotube film includes a plurality of gaps between the adjacent carbon nanotubes so that the carbon nanotube film can have better transparency and higher specific surface area.

The carbon nanotube film is capable of forming a free-standing structure. The term “free-standing structure” can be defined as a structure that does not require a substrate for support. For example, a free standing structure can sustain the weight of itself when it is hoisted by a portion thereof without any damage to its structural integrity. So, if the carbon nanotube drawn film is placed between two separate supporters, a portion of the carbon nanotube drawn film, not in contact with the two supporters, would be suspended between the two supporters and yet maintain film structural integrity. The free-standing structure of the carbon nanotube drawn film is realized by the successive carbon nanotubes joined end to end by Van der Waals attractive force.

The carbon nanotube film has a small and uniform thickness in a range from about 0.5 nm to 10 microns. Since the carbon nanotube film drawn from the carbon nanotube array can form the free-standing structure only by van der Waals forces between the carbon nanotubes, the carbon nanotube film has a large specific surface area. In one embodiment, the specific surface area of the carbon nanotube film measured by the BET method is in a range from about 200 m²/g to 2600 m²/g. A mass per unit area of the carbon nanotube film is in a range from about 0.01 g/m² to about 0.1 g/m² (area here refers to the macro area of the carbon nanotube film). In another embodiment, the mass per unit area of the carbon nanotube film is about 0.05 g/m². Since the carbon nanotube film has minimal thickness and the heat capacity of the carbon nanotube is itself small, the carbon nanotube film has small heat capacity per unit area. In one embodiment, the heat capacity per unit area of the carbon nanotube film is less than 2×10⁻⁴ J/cm²·K.

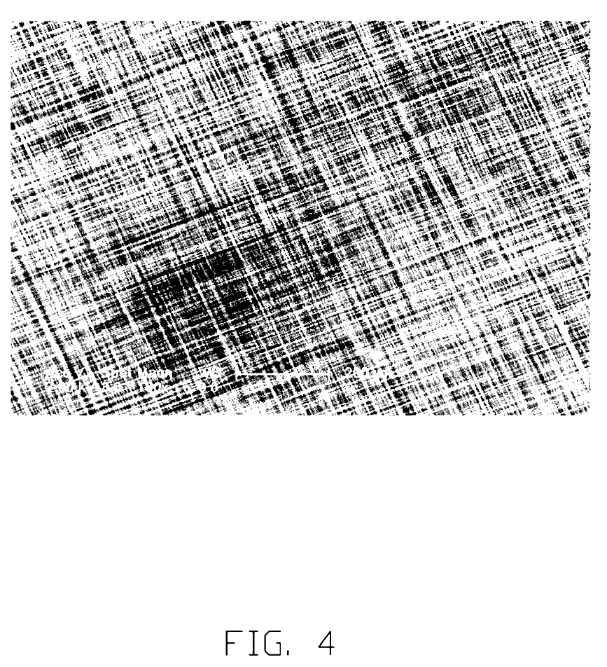

The carbon nanotube film structure 110 may includes at least two stacked carbon nanotube films. In one embodiment, a number of layers of the stacked carbon nanotube film is 50 layers or less. In another embodiment, the number of layers of the stacked carbon nanotube film is 10 layers or less. Additionally, an angle can exist between the orientation of carbon nanotubes in adjacent carbon nanotube films. Adjacent carbon nanotube films can be combined by only Van der Waals attractive forces therebetween without the need of an adhesive. An angle between the aligned directions of the carbon nanotubes in two adjacent carbon nanotube films can range from about 0 degrees to about 90 degrees. In one embodiment, referring to FIG. 4, the carbon nanotube film structure 110 includes at least two stacked carbon nanotube films, and the angle between the aligned directions of the carbon nanotubes in the two adjacent carbon nanotube films is 90 degrees.

The first electrode 120 and the second electrode 122 are electrically connected to the carbon nanotube film structure 110. In one embodiment, the first electrode 120 and the second electrode 122 are directly disposed on the surface of the carbon nanotube film structure 110. The first electrode 120 and the second electrode 122 can input a current to the carbon nanotube film structure 110. In one embodiment, a direct current is input from the first electrode 120 and the second electrode 122 to the carbon nanotube film structure 110. The first electrode 120 and the second electrodes 122 are spaced from each other, and disposed at either end of the carbon nanotube film structure 110.

In one embodiment, the plurality of carbon nanotubes in the carbon nanotube film structure 110 extends from the first electrode 120 to the second electrode 122. When the carbon nanotube film structure 110 consists of one carbon nanotube film, or of at least two films stacked along a same direction (i.e., the carbon nanotubes in different carbon nanotube films being arranged in a same direction and parallel to each other), the plurality of carbon nanotubes of the carbon nanotube film structure 110 extend from the first electrode 120 to the second electrode 122. In one embodiment, the first electrode 120 and the second electrode 122 are linear structures, and are perpendicular to extended directions of the carbon nanotubes of at least one carbon nanotube film in the carbon nanotube film structure 110. In one embodiment, the lengths of the first electrode 120 and the second electrode 122 are same as a length of the carbon nanotube film structure 110, the first electrode 120 and the second electrode 122 thus extending from one end of the carbon nanotube film structure 110 to the other end. Thus, each of the first electrode 120 and the second electrode 122 is connected to two ends of the carbon nanotube film structure 110.

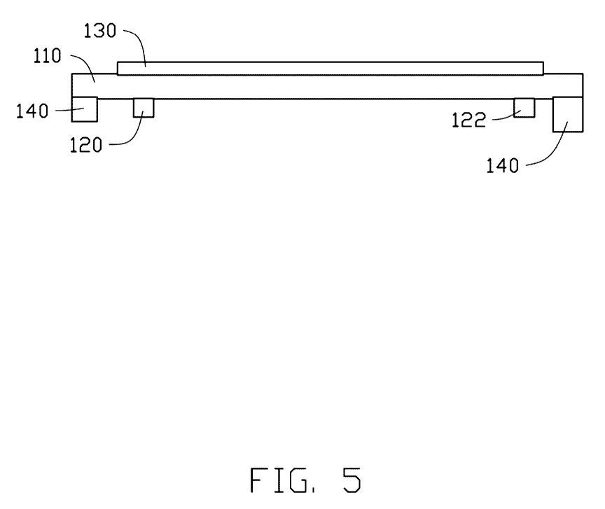

The carbon nanotube film structure 110 is the free-standing structure and can be suspended by the first electrode 120 and second electrode 122. In one embodiment, the first electrode 120 and second electrode 122 have sufficient strength to support the carbon nanotube film structure 110. The first electrode 120 and the second electrode 122 may be conductive wire or conductive rod. Referring to FIG. 5, in another embodiment, the evaporating source 100 may further include a support structure 140 to support the carbon nanotube film structure 110. A portion of the carbon nanotube film structure 110 not in contact with the support structure 140 would be free-standing even though unsuspended. The support structure 140 can be a heat-insulating structure, such as glass, quartz, or ceramic. The first electrode 120 and the second electrode 122 may each be a conductive paste coated on the surface of the carbon nanotube film structure 110. In one embodiment, the support structure 140 comprises at least two supporters spaced from each other. In another embodiment, the support structure 140 can comprise only two spaced supporters. The carbon nanotube film structure 110 is disposed on the two supporters, and thus wholly or partly suspended.

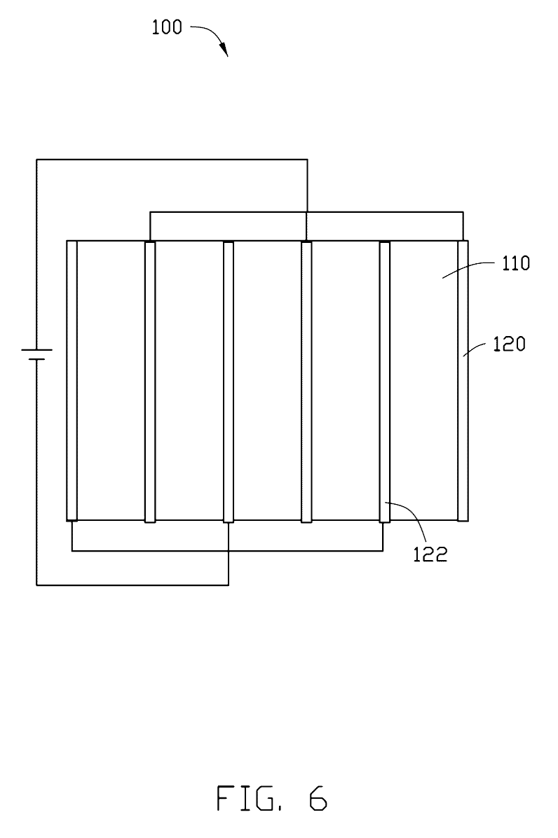

Referring to FIG. 6, in one embodiment, the evaporating source 100 includes a plurality of first electrodes 120 and a plurality of second electrodes 122. The plurality of first electrodes 120 and the plurality of second electrodes 122 are spaced from each other and alternately disposed on the surface of the carbon nanotube film structure 110. One second electrode 122 is disposed between two adjacent first electrodes 120 and one first electrode 120 is disposed between two adjacent second electrodes 122. In one embodiment, the plurality of first electrodes 120 and the plurality of second electrodes 122 are uniformly spaced from each other. The carbon nanotube film structure 110 is divided into a plurality of sub-carbon-nanotube-film-substructures by alternate spacing of the plurality of first electrodes 120 and the plurality of second electrodes 122. The plurality of first electrodes 120 are connected to a positive electrode of an electrical source, the plurality of second electrodes 122 are connected to a negative electrode of the electrical source. The plurality of sub-carbon-nanotube-film-structures are connected in parallel to reduce electrical resistance of the evaporating source 100.

The evaporating material 130 is adhered on and coats the surface of the carbon nanotube film structure 110. Macroscopically, the evaporating material 130 can be seen as a layer formed on at least one surface of the carbon nanotube film structure 110. In one embodiment, the evaporating material 130 is coated on two surfaces of the carbon nanotube film structure 110. The evaporating material 130 and the carbon nanotube film structure 110 form a composite membrane. In one embodiment, a thickness of the composite membrane is less 100 microns or less. In another embodiment, the thickness of the composite membrane is 5 microns or less. Because an amount of the evaporating material 130 carried per unit area of the carbon nanotube film structure 110 is small in microscopic terms a morphology of the evaporating material 130 may be nanoscale particles or layers with nanoscale thickness, being attached to a single carbon nanotube surface or the surfaces of a few carbon nanotubes. In one embodiment, the morphology of the evaporating material 130 is particles. A diameter of the particles is in a range from about 1 nanometer to 500 nanometers. In another embodiment, the morphology of the evaporating material 130 is a layer. A thickness of the evaporating material 130 is in a range from about 1 nanometer to 500 nanometers. The evaporating material 130 can completely cover and coat a single carbon nanotube for all or part of its length. The morphology of the evaporating material 130 coated on the surface of the carbon nanotube film structure 110 is associated to the amount of the evaporating material 130, species of the evaporating material 130, a wetting performance of the carbon nanotubes, and other properties. For example, the evaporation material 130 is more likely to be particle when the evaporation material 130 is not soaked in the surface of the carbon nanotube. The evaporating material 130 is more likely to uniformly coat a single carbon nanotube surface to form a continuous layer when the evaporating material 130 is soaked in the surface of carbon nanotubes. In addition, when the evaporating material 130 is an organic material having high viscosity, it may form a continuous film on the surface of the carbon nanotube film structure 110. No matter what the morphology of the evaporating material 130 may be, the amount of evaporating material 130 carried by per unit area of the carbon nanotube film structure 110 is small. Thus, the electrical power inputted by the first electrode 120 and the second electrode 122 can instantaneously and completely gasify the evaporating material 130. In one embodiment, the evaporating material 130 is completely gasified within 1 second. In another embodiment, the evaporating material 130 is completely gasified within 10 microseconds. The disposition of the evaporating material 130 on the surface of the carbon nanotube film structure 110 is uniform, so that different locations of the carbon nanotube film structure 110 carry substantially equal amounts of the evaporating material 130.

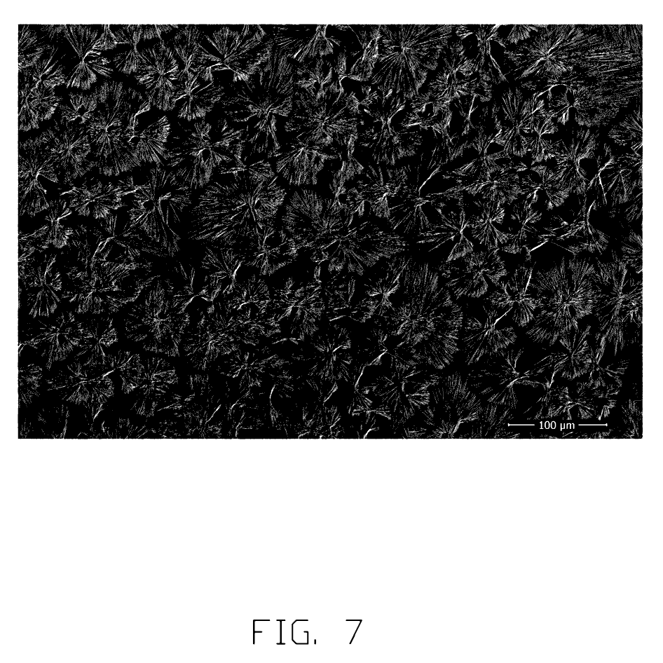

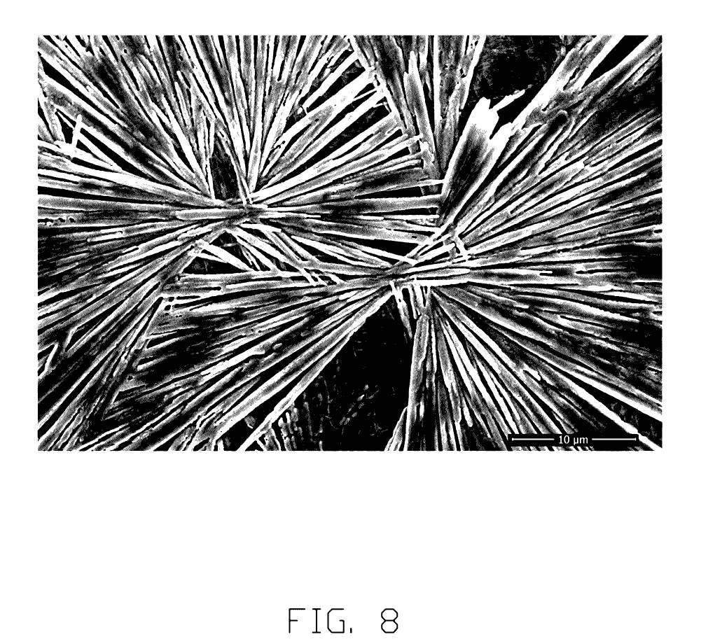

A gasification temperature of the evaporating material 130 is lower than a gasification temperature of the carbon nanotube under same conditions. The evaporating material 130 does not react with the carbon in the vacuum evaporation process. In one embodiment, the evaporating material 130 is an organic material and a gasification temperature of the organic material is less than or equal to 300 □. The evaporating material 130 may be a single material, or may be a mixture of a variety of materials. The evaporating material 130 can be uniformly disposed on the surface of the carbon nanotube film structure 110 by a variety of methods, such as solution method, vapor deposition method, plating method, or chemical plating method. In one embodiment, the evaporating material 130 is previously dissolved or uniformly dispersed in a solvent to form a solution or dispersion. The solution or dispersion is uniformly attached to the carbon nanotube film structure 110. The solvent evaporates, leaving the dried evaporating material uniformly coated on the surfaces of the carbon nanotube film structure 110. When the evaporating material 130 includes a mixture of a variety materials, the variety of materials can be dissolved in a liquid phase solvent and mixed a required ratio in advance, so that the variety of materials can be coated on different locations of the carbon nanotube film structure 110 in the required ratio. Referring FIGS. 7 and 8, in one embodiment, the evaporating material 130 formed on the carbon nanotube film structure 110 is a mixture of methylammonium iodide and lead iodide, and the methylammonium iodide and the lead iodide are uniformly mixed in the mixture.

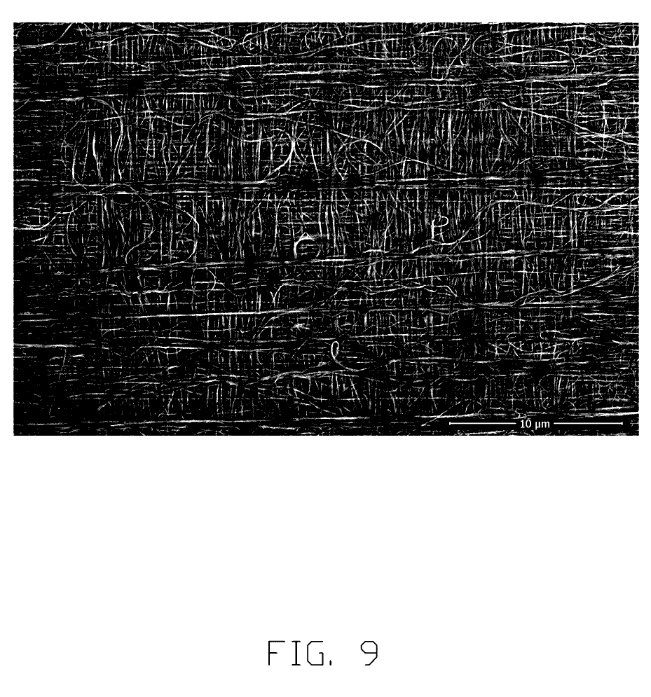

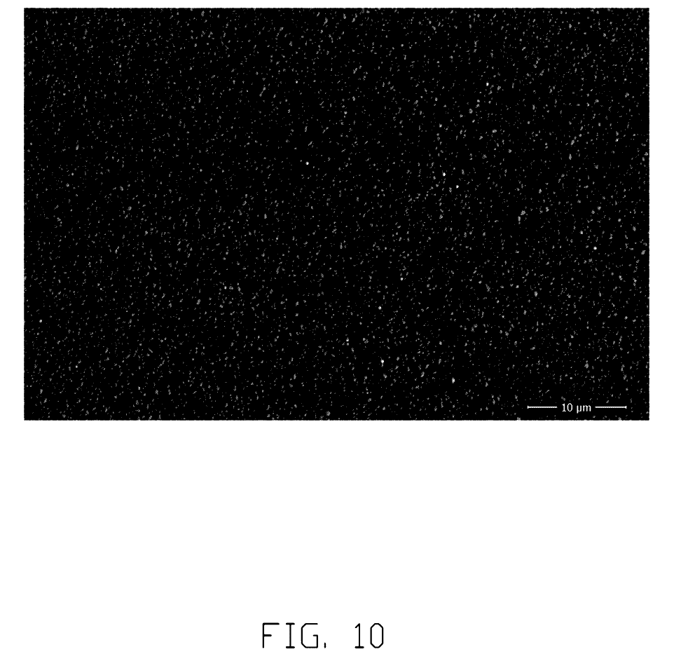

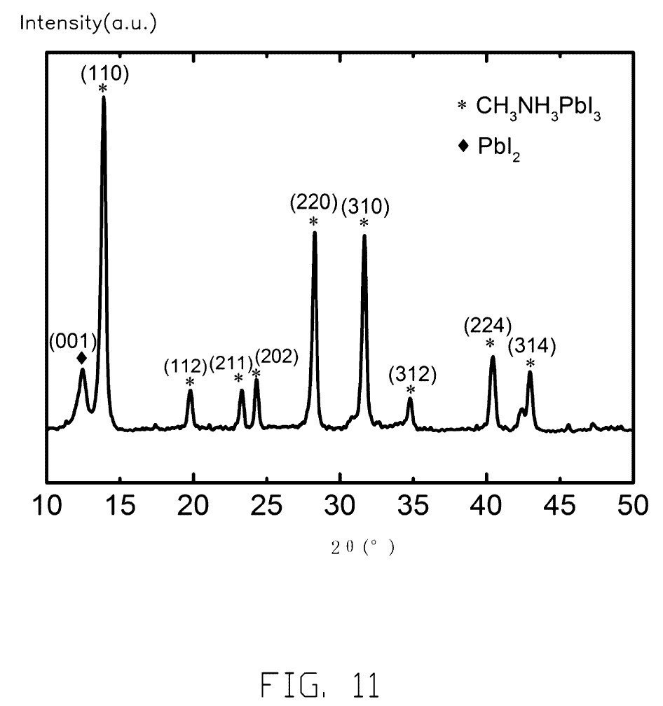

The first electrode 120 and the second electrode 122 input the electrical signals to the carbon nanotube film structure 110. Since the carbon nanotube film structure 110 has a small heat capacity per unit area, the carbon nanotube film structure 110 can convert electrical energy to heat quickly, and a temperature of the carbon nanotube film structure 110 can rise rapidly. Since the carbon nanotube film structure 110 has a large specific surface area and is very thin, the carbon nanotube film structure 110 can rapidly transfer heat to the evaporating material 130. The evaporating material 130 is rapidly heated to a evaporation or sublimation temperature. Since per unit area of the carbon nanotube film structure 110 carries small amount of the evaporating material 130, all the evaporating material 130 may instantly gasify. The carbon nanotube film structure 110 and the depositing substrate 200 are parallel to and spaced from each other. In one embodiment, the distance between the depositing substrate 200 and the carbon nanotube film structure 110 is in a range from about 1 micrometer to about 10 millimeters. Since the distance between the carbon nanotube film structure 110 and the depositing substrate 200 is small, a gaseous evaporating material 130 evaporated from the carbon nanotube film structure 110 is rapidly attached to the depositing surface of the depositing substrate 200 to form a deposited layer. The area of the depositing surface of the depositing substrate 200 is equal or less than the macro area of the carbon nanotube film structure 110. The carbon nanotube film structure 110 can completely cover the depositing surface of the depositing substrate 200. Thus, the evaporating material 130 is evaporated to the depositing surface of depositing substrate 200 as a correspondence to the carbon nanotube film structure 110 to form the deposited layer. Since the evaporating material 130 is uniformly carried by the carbon nanotube film structure 110, the deposited layer is also a uniform structure. Referring FIGS. 9 and 10, in one embodiment, after inputting the electrical current to the carbon nanotube film structure 110, the temperature of the carbon nanotube film structure 110 rises quickly, the mixture of the methylammonium iodide and the lead iodide disposed on the surface of the carbon nanotube film structure 110 is instantly gasified, and a perovskite structure CH₃NH₃PbI₃ film is formed on the depositing surface of the depositing substrate 200. FIG. 9 shows a structure of the evaporating source 100 after vacuum evaporation. After evaporating the evaporating material 130 disposed on the surface structure of the carbon nanotube film structure 110, the carbon nanotube film structure 110 retains the original network structure, and the carbon nanotubes of the carbon nanotube film structure 110 are still joined end to end. FIG. 10 shows that the methylammonium iodide and the lead iodide continue a chemical reaction after gasification, and form a thin film having a uniform thickness on the depositing surface of the depositing substrate 200. Referring to FIG. 11, the thin film can be tested by XRD (X-ray diffraction). The XRD can determine and show as patterns that a material of the thin film is the perovskite structure CH₃NH₃PbI₃.

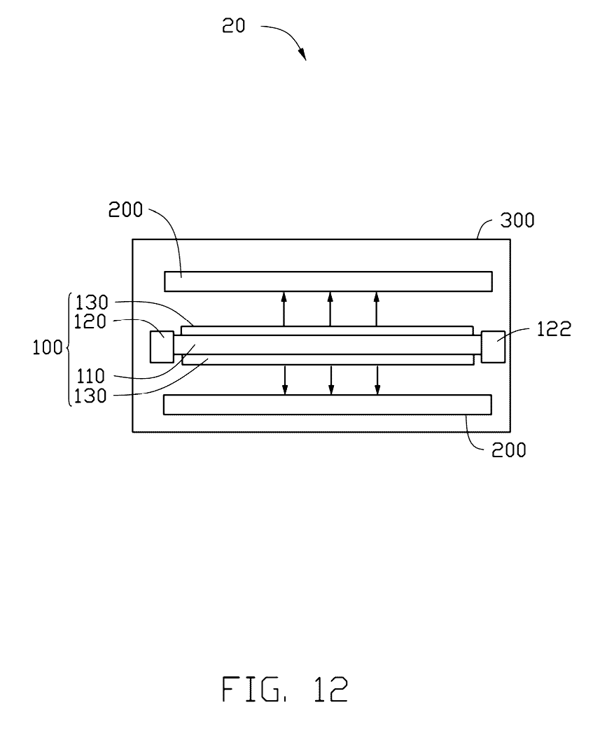

Referring FIG. 12, in one embodiment, the vacuum evaporation apparatus 20 includes two depositing substrates 200. The two depositing substrates 200 are respectively faced to and spaced from the evaporating source 100. The evaporating material 130 is disposed on two surfaces of the carbon nanotube film structure 110. The two depositing substrates 200 are respectively faced to and spaced from the both surfaces of the carbon nanotube film structure 110.

Other characteristics of the vacuum evaporation apparatus 20 are the same as the vacuum evaporation apparatus 10 discussed above.

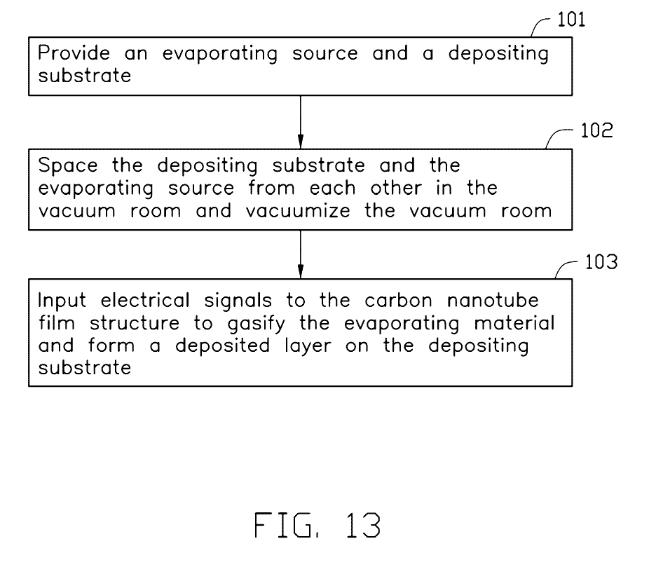

A flowchart is presented in accordance with an example embodiment as illustrated. The embodiment of a vacuum evaporation method 1 is provided by way of example, as there are a variety of ways to carry out the method. The method 1 described below can be carried out using the configurations illustrated in FIGS. 1 to 12 for example, and various elements of these figures are referenced in explaining example method 1. Each block shown in FIG. 13 represents one or more processes, methods, or subroutines carried out in the exemplary method 1. Additionally, the illustrated order of blocks is by example only and the order of the blocks can be changed. The exemplary method 1 can begin at block 101. Depending on the embodiment, additional steps can be added, others removed, and the ordering of the steps can be changed.

At block 101, an evaporating source 100 and a depositing substrate 200 are provided. The evaporating source 100 comprises an evaporating material 130, a carbon nanotube film structure 110, a first electrode 120, and a second electrode 122. The first electrode 120 and the second electrode 122 are spaced from each other and electrically connected to the carbon nanotube film structure 110. The carbon nanotube film structure 110 is a carrying structure for the evaporating material 130. The evaporating material 130 is located on a surface of the carbon nanotube film structure 110.

At block 102, the depositing substrate 200 and the evaporating source 100 are faced to and spaced from each other in the vacuum room 300. The vacuum room 300 is vacuumized.

At block 103, the carbon nanotube film structure 110 is inputted electrical signals to gasify the evaporating material 130 and form a deposited layer.

At block 101, a method for fabricating the evaporating source 100 includes the steps of: (11) providing the carbon nanotube film structure 110, the first electrode 120, and the second electrode 122, wherein the first electrode 120 and the second electrode 122 are spaced from each other and electrically connected to the carbon nanotube film structure 110; (12) carrying the evaporating material 130 on the surface of the carbon nanotube film structure 110.

In step (11), a position of the carbon nanotube film structure 110 between the first electrode 120 and the second electrode 122 is suspended.

In step (12), the evaporating material 130 is disposed on the surface of the carbon nanotube film structure 110 by a variety of methods, such as solution method, vapor deposition method, plating method or chemical plating method. The deposition method may be chemical vapor deposition (CVD) method or physical vapor deposition (PVD) method.

A solution method for disposing the evaporating material 130 on the surface of the carbon nanotube film structure 110 includes the steps of: (121) dissolving or uniformly dispersing the evaporating material 130 in a solvent to form a solution or dispersion; (122) uniformly attaching the solution or dispersion to the carbon nanotube film structure 110 by spray coating method, spin coating method, or dip coating method; (123) evaporating and drying the solvent to make the evaporating material 130 uniformly attach on the surface of the carbon nanotube film structure 110.

When the evaporating material 130 includes a variety of materials, the variety of materials can be dissolved in a liquid phase solvent and mixed with a required ratio in advance, so that the variety of materials can be disposed on different locations of the carbon nanotube film structure 110 by the required ratio.

At block 102, the depositing substrate 200 and the evaporating source 100 are faced to and spaced from each other. In one embodiment, a distance between the depositing surface of the depositing substrate 200 and the carbon nanotube film structure 110 of the evaporating source 100 is substantially equal. The carbon nanotube film structure 110 is substantially parallel to the depositing surface of the depositing substrate 200, and the area of the depositing surface of the depositing substrate 200 is equal or less than the macro area of the carbon nanotube film structure 110. Thus, a gaseous evaporating material 130 can reach the depositing surface of the depositing substrate 200 substantially at the same time.

At block 103, the electrical signal is inputted to the carbon nanotube film structure 110 through the first electrode 120 and the second electrode 122. When the electric signal is a direct current signal, the first electrode 120 and the second electrode 122 are respectively electrically connected to the positive and negative of a direct current source. The direct current power inputs the direct current signal to the carbon nanotube film structure 110 through the first electrode 120 and the second electrode 122. When the electrical signal is a alternating current signal, the first electrode 120 is electrically connected to a alternating current source, and the second electrode 122 is connected to earth. The temperature of the carbon nanotube film structure 110 can reach a gasification temperature of the evaporating material 130 by inputting an electrical signal power to the evaporating source 100. The electrical signal power can be calculated according to the formula σT⁴S. Wherein σ represents Stefan-Boltzmann constant; T represents the gasification temperature of the evaporating material 130; and S represents the macro area of the carbon nanotube film structure 110. The larger the macro area of the carbon nanotube film structure 110 and the higher the gasification temperature of the evaporating material 130, the greater the electrical signal power. Since the carbon nanotube film structure 110 has a small heat capacity per unit area, the carbon nanotube film structure 110 can quickly generate thermal response to rise temperature. Since the structure of the carbon nanotube film structure 110 has a large specific surface area, the structure of the carbon nanotube film structure 110 can quickly exchange heat with surrounding medium, and heat signals generated by the carbon nanotube film structure 110 can quickly heat the evaporating material 130. Since the amount of the evaporating material 130 disposed on per unit macro area of the carbon nanotube film structure 110 is small, the evaporating material 130 can be completely gasified instantly by the heat signals. Therefore, the evaporating material 130 can reach and disposed on locations of the depositing surface of the depositing substrate 200 corresponding to locations of the evaporating material 130 disposed on the surface of the carbon nanotube film structure 110. Since the amount of the evaporating material 130 disposed on different locations of the carbon nanotube film structure 110 is same (the evaporating material 130 is uniformly disposed on the carbon nanotube film structure 110), the deposited layer formed on the depositing surface of the depositing substrate 200 has uniform thickness. Thus, thickness and uniformity of the deposited layer are related to the amount and uniformity of the evaporating material 130 disposed on the carbon nanotube film structure 110. When the evaporating material 130 includes a variety of materials, a proportion of the variety of materials is same in different locations of the carbon nanotube film structure 110. Thus, the variety of materials still has same proportion in the gaseous evaporating material 130, a uniform deposited layer can be formed on the depositing surface of the depositing substrate 200.

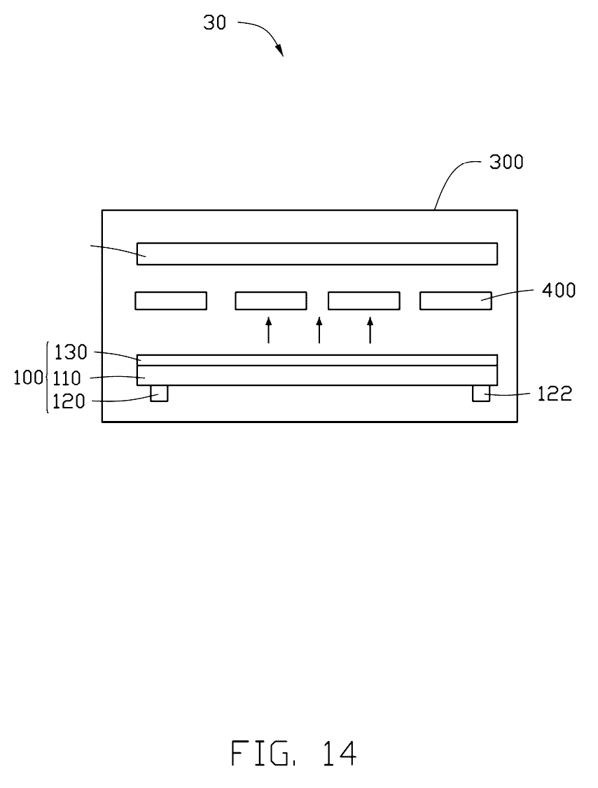

Referring to FIG. 14, one embodiment of a vacuum evaporation apparatus 30 is provided. The vacuum evaporation apparatus 10 comprises an evaporating source 100, a depositing substrate 200, a vacuum room 300, and a grid 400. The evaporating source 100, the depositing substrate 200 and the grid 400 are disposed in the vacuum room 300. The depositing substrate 200 and the evaporating source 100 are faced to and spaced from each other. In one embodiment, a distance between the depositing substrate 200 and the evaporating source 100 is ranged from about 1 micrometer to about 10 millimeters. The grid 400 is disposed between the depositing substrate 200 and the evaporating source 100.

The grid 400 includes at least one through hole. A gaseous evaporating material 130 can passes through the through hole to reach the depositing surface of the depositing substrate 200. A thickness of the grid 400 is small. In one embodiment, the thickness of the grid 400 is in a range from about 1 micrometer to about 5 millimeters. The through hole may have a required shape and size. The gaseous evaporating material 130 is instantly adhered to the depositing surface of the depositing substrate 200 to form a patterned deposited layer after passing through the through hole. A pattern of the patterned deposited layer is corresponding to the required shape and size of the through hole of the grid 400. A number, shape and size of the through hole are not limited to, can be designed according to need. The location of the through hole in the grid 400 is corresponding to the required location of the patterned deposited layer formed on the depositing surface of the depositing substrate 200. In one embodiment, the grid 400 is sandwiched between and in direct contact with the depositing surface of the depositing substrate 200 and the carbon nanotube film structure 110. In another embodiment, the grid 400 are respectively spaced from the depositing surface of the depositing substrate 200 and the carbon nanotube film structure 110.

Other characteristics of the vacuum evaporation apparatus 30 are the same as the vacuum evaporation apparatus 10 discussed above.

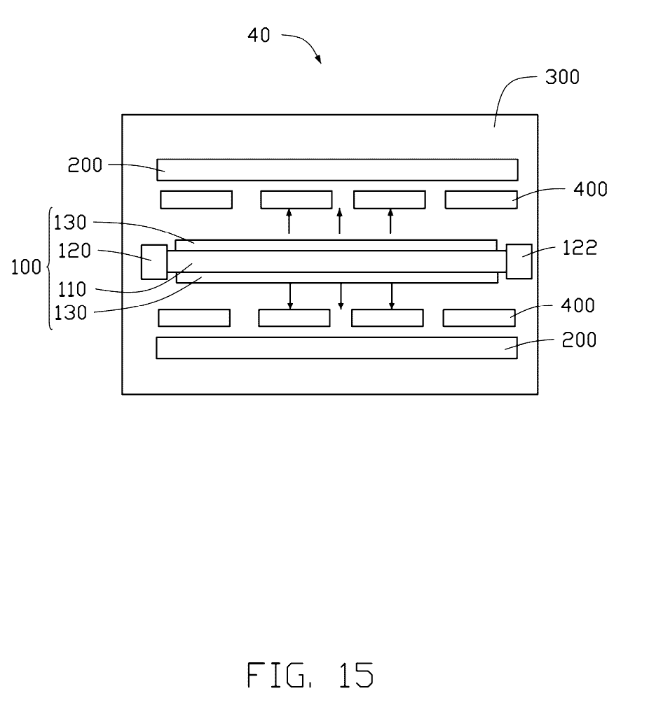

Referring to FIG. 15, another embodiment of a vacuum evaporation apparatus 40 is provided. The vacuum evaporation apparatus 10 comprises a evaporating source 100, two depositing substrates 200, a vacuum room 300, and two grids 400. The two depositing substrates 200 are respectively faced to and spaced from two surfaces of the carbon nanotube film structure 110. The two grids 400 are respectively located or sandwiched between the two depositing substrates 200 and the evaporating source 100. The evaporating material 130 are disposed on the two surfaces of the carbon nanotube film structure 110. The two depositing substrates 200 are respectively faced to and spaced from two surfaces of the carbon nanotube film structure 110.

Other characteristics of the vacuum evaporation apparatus 40 are the same as the vacuum evaporation apparatus 20 discussed above.

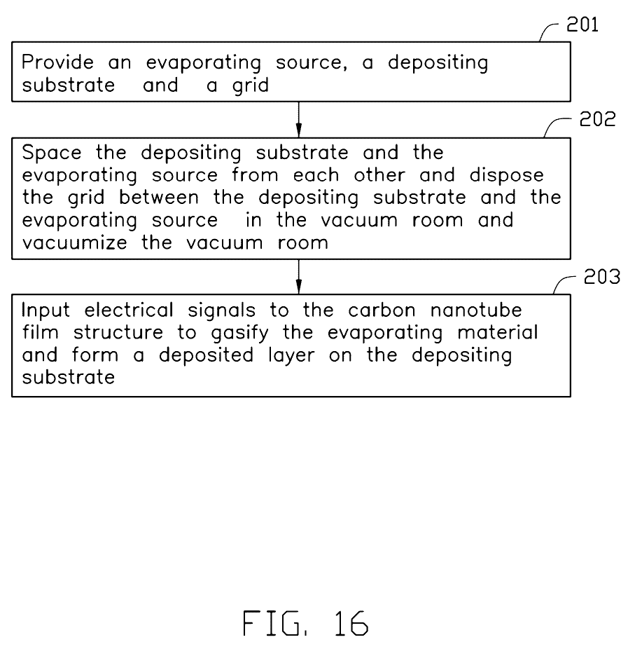

A flowchart is presented in accordance with an example embodiment as illustrated. The embodiment of a vacuum evaporation method 2 is provided by way of example, as there are a variety of ways to carry out the method. The method 2 described below can be carried out using the configurations illustrated in FIGS. 14 to 15 for example, and various elements of these figures are referenced in explaining example method 2. Each block shown in FIG. 16 represents one or more processes, methods, or subroutines carried out in the exemplary method 2. Additionally, the illustrated order of blocks is by example only and the order of the blocks can be changed. The exemplary method 2 can begin at block 201. Depending on the embodiment, additional steps can be added, others removed, and the ordering of the steps can be changed.

At block 201, an evaporating source 100, a depositing substrate 200 and a grid 400 are provided. The evaporating source 100 comprises the evaporating material 130, the carbon nanotube film structure 110, the first electrode 120, and the second electrode 122. The first electrode 120 and the second electrode 122 are spaced from each other and electrically connected to the carbon nanotube film structure 110. The carbon nanotube film structure 110 is a carrying structure for the evaporating material 130. The evaporating material 130 is located on the surface of the carbon nanotube film structure 110.

At block 202, the depositing substrate 200, the evaporating source 100 and the grid 400 are disposed in the vacuum room 300. The evaporating source 100 is faced to and spaced from the depositing substrate 200, the grid 400 is located or sandwiched between the depositing substrate 200 and the evaporating source 100. The vacuum room 300 is vacuumized.

At block 203, the carbon nanotube film structure 110 is inputted the electrical signals to gasify the evaporating material 130 and form the patterned deposited layer on the depositing surface of the depositing substrate 200.

The block 201 is substantially the same as the block 101 except the evaporating source 100 includes the grid 400.

At block 202, the depositing substrate 200 and the evaporating source 100 are faced to and spaced from each other. In one embodiment, a distance between the depositing surface of the depositing substrate 200 and the carbon nanotube film structure 110 of the evaporating source 100 is substantially equal. The carbon nanotube film structure 110 is substantially parallel to the depositing surface of the depositing substrate 200, and the depositing surface of the depositing substrate 200 is smaller than or equal to the macro area of the carbon nanotube film structure 110. Thus, a gaseous evaporating material 130 can reach the depositing surface of the depositing substrate 200 substantially at the same time when the evaporating material 130 is evaporated. The grid 400 is located or sandwiched between the depositing substrate 200 and the evaporating source 100. The location of the through hole in the grid 400 is corresponding to the required location of the patterned deposited layer formed on the depositing surface of the depositing substrate 200. In one embodiment, the depositing substrate 200, the grid 400, and the evaporating source 100 are stacked, and the grid 400 is respectively in direct contact with the depositing surface of the depositing substrate 200 and the carbon nanotube film structure 110. In another embodiment, the grid 400 is respectively spaced from the depositing surface of the depositing substrate 200 and the carbon nanotube film structure 110. The grid 400 is respectively parallel to the depositing surface of the depositing substrate 200 and the carbon nanotube film structure 110

The block 203 is substantially the same as the block 103. Because the gaseous evaporating material 130 can only pass through the through hole in the grid 400 to reach the depositing surface of the depositing substrate 200, the location of the depositing surface of the depositing substrate 200 corresponding to the through hole in the grid 400 can form the deposited layer. Thus, the deposited layer is the patterned deposited layer. The pattern of the patterned deposited layer is corresponding to the pattern of the through hole. When the material of the evaporating material 130 is the organic material, it is difficult to form the patterned deposited layer by the conventional mask etching method, such as photoetching method. Further, the conventional photoetching method is difficult to achieve high accuracy to form the patterned deposited layer. In the vacuum evaporation method 2, the patterned deposited layer can be once formed on the depositing surface of the depositing substrate 200 by using the grid 400 having required pattern. Thus, the patterned deposited layer with high accuracy can be formed by eliminating process of the conventional mask etching.

The carbon nanotube film is free-standing structure and used to carry material. The carbon nanotube film has large specific surface area and good uniformity, so that the evaporating material carried by the carbon nanotube film can uniformly distributed on the carbon nanotube film before evaporation. The carbon nanotube film can be heated instantaneously, thus the evaporating material can be completely gasified in a short time to form a uniform gaseous evaporating material distributed in large area. The distance between the depositing substrate and the carbon nanotube film is small, thus the evaporating material carried on the carbon nanotube film can be substantially utilized to save the evaporating material and improve the deposition rate.

Even though numerous characteristics and advantages of certain inventive embodiments have been set out in the foregoing description, together with details of the structures and functions of the embodiments, the disclosure is illustrative only. Changes may be made in detail, especially in matters of arrangement of parts, within the principles of the present disclosure to the full extent indicated by the broad general meaning of the terms in which the appended claims are expressed.

Depending on the embodiment, certain of the steps of methods described may be removed, others may be added, and the sequence of steps may be altered. It is also to be understood that the description and the claims drawn to a method may comprise some indication in reference to certain steps. However, the indication used is only to be viewed for identification purposes and not as a suggestion as to an order for the steps.

The embodiments shown and described above are only examples. Even though numerous characteristics and advantages of the present technology have been set forth in the foregoing description, together with details of the structure and function of the present disclosure, the disclosure is illustrative only, and changes may be made in the detail, especially in matters of shape, size and arrangement of the parts within the principles of the present disclosure up to, and including the full extent established by the broad general meaning of the terms used in the claims. It will therefore be appreciated that the embodiments described above may be modified within the scope of the claims.

What is claimed is:

1. A vacuum evaporation method comprising:
S1, providing an evaporating source and a depositing substrate, wherein the evaporating source comprises an evaporating material, a carbon nanotube film structure, a first electrode, and a second electrode; the first electrode and the second electrode are spaced from each other and electrically connected to the carbon nanotube film structure; and the evaporating material is located on a surface of the carbon nanotube film structure;
S2, spacing the depositing substrate and the evaporating source from each other in a vacuum room and vacuumizing the vacuum room; and
S3, inputting electrical signals to the carbon nanotube film structure from the first electrode and the second electrode to gasify the evaporating material to form a deposited layer on the depositing substrate.

2. The vacuum evaporation method of claim 1, wherein a method for fabricating the evaporating source comprising:
S11, providing the carbon nanotube film structure, the first electrode, and the second electrode, wherein the first electrode and the second electrode are spaced from each other and electrically connected to the carbon nanotube film structure;
S12, disposing the evaporating material on a surface of the carbon nanotube film structure by solution method, vapor deposition method, plating method or chemical plating method.

3. The vacuum evaporation method of claim 2, wherein the solution method for disposing the evaporating material on the surface of the carbon nanotube film structure comprising:
S121, dispersing the evaporating material in a solvent to form a solution or dispersion;
S122, attaching the solution or dispersion to the carbon nanotube film structure;
S123, drying the solvent to make the evaporating material uniformly attach on the surface of the carbon nanotube film structure.

4. The vacuum evaporation method of claim 1, wherein the evaporating material comprises a variety of materials, and the variety of materials are dissolved in a liquid phase solvent and mixed with each other.

5. The vacuum evaporation method of claim 4, wherein a thickness of the evaporating source is less than or equal to 100 micrometers.

6. The vacuum evaporation method of claim 1, wherein the carbon nanotube film structure is suspended by the first electrode and the second electrode, and
>the evaporating material is located on a suspended surface of the carbon nanotube film structure.

7. The vacuum evaporation method of claim 1, wherein a heat capacity per unit area of the carbon nanotube film structure is less than 2×10⁻⁴ J/cm²·K, and a specific surface area of the carbon nanotube film structure is larger than 200 m²/g.

8. The vacuum evaporation method of claim 1, wherein the carbon nanotube film structure comprises at least one carbon nanotube film, the least one carbon nanotube film comprises a plurality of nanotubes joined end to end by Van der Waals attractive force.

9. The vacuum evaporation method of claim 8, wherein the at least one carbon nanotube film comprises a first surface, and the plurality of carbon nanotubes of the at least one carbon nanotube film are arranged substantially parallel to the first surface of the at least one carbon nanotube film and oriented along a same direction.

10. The vacuum evaporation method of claim 1, wherein the depositing substrate is parallel to the carbon nanotube film structure, and a distance between the depositing substrate and the carbon nanotube film structure is in a range from about 1 micrometer to about 10 millimeters.

11. A vacuum evaporation method comprising:
S1, providing an evaporating source, a depositing substrate and a grid, wherein the evaporating source comprises an evaporating material, a carbon nanotube film structure, a first electrode, and a second electrode; the first electrode and the second electrode are spaced from each other and electrically connected to the carbon nanotube film structure; and the evaporating material is located on a surface of the carbon nanotube film structure;
S2, spacing the depositing substrate and the evaporating source from each other and disposing the grid between the depositing substrate and the evaporating source in a vacuum room and vacuumizing the vacuum room.; and
S3, inputting electrical signals to the carbon nanotube film structure from the first electrode and the second electrode to gasify the evaporating material to form a deposited layer on the depositing substrate.

12. The vacuum evaporation method of claim 11, wherein the evaporating material comprises a variety of materials, and the variety of materials are dissolved in a liquid phase solvent and mixed with each other.

13. The vacuum evaporation method of claim 11, wherein the grid is sandwiched between and in direct contact with the depositing substrate and the carbon nanotube film structure.

14. The vacuum evaporation method of claim 11, wherein the grid comprises at least one through hole.

15. The vacuum evaporation method of claim 11, wherein a heat capacity per unit area of the carbon nanotube film structure is less than 2×10⁻⁴ J/cm²·K, and a specific surface area of the carbon nanotube film structure is larger than 200 m²/g.

16. The vacuum evaporation method of claim 11, wherein the carbon nanotube film structure comprises at least one carbon nanotube film, and the at least one carbon nanotube film comprises a plurality of carbon nanotubes joined end to end by Van der Waals attractive force.

17. The vacuum evaporation method of claim 16, wherein the at least one carbon nanotube film comprises a first surface, and the plurality of carbon nanotubes of the at least one carbon nanotube film are arranged substantially parallel to the first surface of the at least one carbon nanotube film and oriented along a same direction.

18. The vacuum evaporation method of claim 11, wherein a thickness of the evaporating source is less than or equal to 100 micrometers.

19. The vacuum evaporation method of claim 11, wherein the evaporating material is a mixture of methylammonium iodide and lead iodide.

20. The vacuum evaporation method of claim 11, wherein the depositing substrate are parallel to the carbon nanotube film structure, and a distance between the depositing substrate and the carbon nanotube film structure is in a range from about 1 micrometer to about 10 millimeters.
